(19) United States
(12) Patent Application Publication
(10) Pub. No.: US 2008/0020487 A1
(43) Pub. Date: Jan. 24, 2008

(54) Alignment of carbon nanotubes on a substrate via solution deposition

(76) Inventors: Robert Scott McLean, Hockessin, DE (US); Ming Zheng, Wilmington, DE (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/225,442

(22) Filed: Sep. 13, 2005

Related U.S. Application Data
(60) Provisional application No. 60/610,449, filed on Sep. 16, 2004.
(60) Provisional application No. 60/633,142, filed on Dec. 3, 2004.

(51) Int. Cl. H01L 21/00

(52) U.S. Cl. 438/1

(57) ABSTRACT

Carbon nanotubes, associated with a charged dispersant are aligned on a substrate by deposition on the substrate directly from solution. Preferred dispersants are charged polymers such as biopolymers.

### FIELD OF THE INVENTION

The present invention relates to methods for aligning carbon nanotubes on a substrate. More specifically carbon nanotubes are aligned on a substrate after deposition from solution.

### BACKGROUND OF THE INVENTION

Carbon nanotubes (CNT) have been the subject of intense research since their discovery in 1991. CNTs possess unique properties such as small size, considerable stiffness, and electrical conductivity, which makes them suitable in a wide range of applications, including use as structural materials and in molecular electronics, nanoelectronic components, and field emission displays. Carbon nanotubes may be either multi-walled (MWNTs) or single-walled (SWNTs), and have diameters in the nanometer range.

Depending on their atomic structure CNT's may have either metallic or semiconductor properties. These properties, in combination with their small dimensions makes CNT's particularly attractive for use in fabrication of nano-devices. A major obstacle to such efforts has been the difficulty in manipulating the nanotubes. Aggregation is particularly problematic because the highly polarized, smooth-sided fullerene tubes readily form parallel bundles or ropes with a large van der Waals binding energy. This bundling perturbs the electronic structure of the tubes, and it confounds all attempts to separate the tubes by size or type or to use them as individual macromolecular species. Various methods have been used to disperse carbon nanotubes. For example, commonly owned in U.S. Patent Appl. 20040132072 and WO 2004/048256, teaches that nucleic acid molecules are able to singly disperse high concentrations of bundled carbon nanotubes in an aqueous solution.

The usefulness of CNTs in the fabrication of devices, especially nanodevices, would be increased if they could be physically aligned on a substrate. Various methods have been used to align ropes of dispersed SWNT. Q. Chen et al., (Applied Physics Letters (2001), 78, 3714) used electrical fields while filtering dispersions of SWNTs to form thick films of aligned nanotubes. Sallem G. Rao et al., (Nature (2003), 425, 36) used chemically functionalized patterns on a substrate to align sonicated SWNTs. Yu Huang et al., (Science, Vol. 291, pg 630-633) formed aligned nanostructures by passing suspensions of nanowires through fluidic channels between a substrate and a mold. R. Smalley et al. (WO 01/30694) showed alignment of nanotube ropes in the presence of a 25 Tesla magnetic field.

The problem to be solved, therefore, is to provide a method for the facile and inexpensive alignment of bundled carbon nanotubes for use in the fabrication of nano-devices. Applicants have solved the stated problem through the discovery that solutions of dispersed and solubilized carbon nanotubes will align during deposition on a substrate.

### SUMMARY OF THE INVENTION

The present invention relates to methods of aligning carbon nanotubes (CNT) on a solid surface or substrate. The method involves dissolving the CNT's in a solution where the CNT's are in association with a charged dispersant, preferably a polymeric dispersant. The CNT's are then deposited on the substrate from the solution and spontaneously align. Optionally the aligned CNT's may be dried on the surface of the substrate and further processed.

Accordingly in one embodiment the invention provides a method for aligning a population of carbon nanotubes on a substrate comprising:
a) providing a population of carbon nanotubes associated with a charged dispersant in solution;
b) depositing the solution of (a) on a substrate whereby the population of carbon nanotubes are aligned.

In similar fashion the invention provides a method for affixing a population of aligned carbon nanotubes on a substrate comprising:
a) providing a population of carbon nanotubes associated with a charged dispersant in solution;
b) depositing the solution of (a) on a substrate whereby the population of carbon nanotubes are aligned;
c) washing the substrate of (b) with a washing solvent; and
d) drying the washed substrate of (c) whereby the aligned carbon nanotubes are affixed to the substrate.

Substrates made by the above methods are additionally provided as well as devices comprising the same.

In an alternate embodiment the invention provides a method of obtaining a population of carbon nanotubes of uniform length comprising:
a) providing a population of carbon nanotubes associated with a charged dispersant in solution;
b) depositing the solution of (a) on a substrate whereby the population of CNT are aligned;
c) washing the substrate of (b) with a washing solvent;
d) drying the washed substrate of (c) whereby the aligned carbon nanotubes are affixed to the substrate; and
e) cutting the aligned carbon nanotubes affixed to the substrate to a defined length.

### BRIEF DESCRIPTION OF THE FIGURES

FIG. 1 shows an AFM image of the alignment orientation of DNA wrapped CNT deposited on a SiO₂ surface at different spots (1400 μm×1400 μm area).

FIG. 2 shows an AFM image of the alignment orientation of DNA wrapped CNT deposited on a glass surface.

FIG. 3 shows the scheme for depositing DNA wrapped CNT under the influence of an external magnetic field.

FIG. 4 shows an AFM image of the alignment orientation of DNA wrapped CNT deposited on a SiO₂ surface at different spots (1400 μm×1400 μm area) under the influence of an external magnetic field.

FIG. 5 shows AFM and MFM images of CNT deposited on a SiO₂ surface at different spots (3 μm×3 μm area), before and after DNA removal.

FIG. 6 shows AFM images of CNT deposited on a pretreated SiO₂ surface at different spots.

FIG. 7 shows AFM images of DNA-CNT alignment direction in the middle of an gold electrode pair.

### DETAILED DESCRIPTION OF THE INVENTION

The invention places in the hands of the skilled person a means for rapidly and inexpensively aligning CNT's on a solid surface. In preferred embodiments the CNT's are singly dispersed, adding to their utility.

Aligned CNT's are needed in the fabrication of nano-conducting devices where alignment allows for facile synthesis of desirable electrical structures.

The following definitions and abbreviations are to be use for the interpretation of the claims and the specification.

“CNT” means carbon nanotube

“DNA” means deoxyribonucleic acid

“MWNT” means multi-walled nanotube

“PNA” means peptide nucleic acid

“RNA” means ribonucleic acid

“SWNT” means single walled nanotube.

The term “carbon nanotube” refers to a hollow article composed primarily of carbon atoms. The carbon nanotube can be doped with other elements, e.g., metals. The nanotubes typically have a narrow dimension (diameter) of about 1-200 nm and a long dimension (length), where the ratio of the long dimension to the narrow dimension, i.e., the aspect ratio, is at least 5. In general, the aspect ratio is between 10 and 2000.

As used herein a “nucleic acid molecule” is defined as a polymer of RNA, DNA, or peptide nucleic acid (PNA) that is single- or double-stranded, optionally containing synthetic, non-natural or altered nucleotide bases. A nucleic acid molecule in the form of a polymer of DNA may be comprised of one or more segments of cDNA, genomic DNA or synthetic DNA.

The letters “A”, “G”, “T”, “C” when referred to in the context of nucleic acids will mean the purine bases adenine (C₅H₅N₅) and guanine (C₅H₅N₅O) and the pyrimidine bases thymine (C₅H₆N₂O₂) and cytosine (C₄H₅N₃O), respectively.

The term “peptide nucleic acids” refers to a material having stretches of nucleic acid polymers linked together by peptide linkers.

The term “charged dispersant” means an ionic compound that can function as a dispersant or surfactant. The charged dispersant can be anionic or cationic, and can be a single compound or polymeric.

The term “associated with a charged dispersant” when used in the context of a dispersant associated with a carbon nanotube means that the dispersant is in physical contact with the nanotube, covalently or non-covalently. The nanotube surface should be substantially covered by the dispersant. The dispersant can be associated in a periodic manner with the nanotube. By “periodic” it is meant that the dispersant is associated with the nanotube at approximately regular intervals Typical dispersants of the invention are polymers and bio-polymers such as DNA which are wrapped around the carbon nanotube and associated via hydrogen bonding effects.

The term “nanotube-nucleic acid complex” means a composition comprising a carbon nanotube loosely associated with at least one nucleic acid molecule. Typically the association between the nucleic acid and the nanotube is by van der Waals bonds or some other non-covalent means.

The term “aligned” as used herein in reference to the placement of carbon nanotubes on a substrate refers the orientation of an individual nanotube or aggregate of nanotubes with respect to the others (i.e., aligned versus non-aligned). As used herein the term “aligned” may also refer to a 2 dimensional orientation of nanotubes laying relatively flat on a substrate.

The term “substrate” means any solid surface that is stable under process conditions.

The term “uniform length” as applied to a population of aligned carbon nanotubes means the tubes are of a relatively uniform dimension of length.

Carbon Nanotubes

Carbon nanotubes of the invention are generally about 0.5-2 nm in diameter where the ratio of the length dimension to the narrow dimension, i.e., the aspect ratio, is at least 5. In general, the aspect ratio is between 10 and 2000. Carbon nanotubes are comprised primarily of carbon atoms, however may be doped with other elements, e.g., metals. The carbon-based nanotubes of the invention can be either multi-walled nanotubes (MWNTs) or single-walled nanotubes (SWNTs). A MWNT, for example, includes several concentric nanotubes each having a different diameter. Thus, the smallest diameter tube is encapsulated by a larger diameter tube, which in turn, is encapsulated by another larger diameter nanotube. A SWNT, on the other hand, includes only one nanotube.

Carbon nanotubes (CNT) may be produced by a variety of methods, and additionally are commercially available. Methods of CNT synthesis include laser vaporization of graphite (A. Thess et al. Science 273, 483 (1996)), arc discharge (C. Journet et al., Nature 388, 756 (1997)) and HiPCo (high pressure carbon monoxide) process (P. Nikolaev et al. Chem. Phys. Lett. 313, 91-97 (1999)). Chemical vapor deposition (CVD) can also be used in producing carbon nanotubes (J. Kong et al. Chem. Phys. Lett. 292, 567-574 (1998). Additionally CNT's may be grown via catalytic processes both in solution and on solid substrates (Yan Li, et al., Chem. Mater.; 2001; 13(3); 1008-1014); (N. Franklin and H. Dai Adv. Mater. 12, 890 (2000); A. Cassell et al. J. Am. Chem. Soc. 121, 7975-7976 (1999)).

Dispersants

Dispersants are well-known in the art and a general description can be found in “Disperse Systems and Dispersants”, Rudolf Heusch, Ullmann's Encyclopedia of Industrial Chemistry, DOI: 10.1002/14356007.a08_{—}577. The invention provides carbon nanotubes that are dispersed in solution, preferably singly dispersed. A number of dispersants may be used for this purpose wherein the dispersant is associated with the carbon nanotube by covalent or non-covalent means. The dispersant should preferably substantially cover the length of the nanotube, preferably at least half of the length of the nanotube, more preferably substantially all of the length. The dispersant can be associated in a periodic manner with the nanotube, such as wrapping. Preferred dispersants of the invention are charged polymers. In one embodiment synthetic polymers may be suitable as dispersants where they are of suitable charge and length to sufficiently disperse the nanotubes. Examples of polymers that could be suitable for the present invention include but are not limited to those described in M. O'Connell et al., Chem. Phys. Lett., 342, 265, 2001 and WO 02/076888.

The solvent used for the nanotube dispersion can be any solvent that will dissolve the dispersant. The choice of solvent is not critical provided the solvent is not detrimental to the nanotubes or dispersant, and may be a mixture. Preferably the solution is water or aqueous based, optionally containing buffers, salts, and/or chelators.

In a preferred embodiment the dispersant will be a bio-polymer. Bio-polymers particularly suited for the invention include those described in WO 2004/048255, herein incorporated in entirely by reference

Bio-Polymers

Bio-polymers of the invention include those comprised of nucleic acids and polypeptides. Polypeptides may be suitable as dispersants in the present invention if they suitable charge and length to sufficiently disperse the nanotubes. Bio-polymers particularly well suited for singly dispersing carbon nanotubes are those comprising nucleic acid molecules. Nucleic acid molecules of the invention may be of any type and from any suitable source and include but are not limited to DNA, RNA and peptide nucleic acids. The nucleic acid molecules may be either single stranded or double stranded and may optionally be functionalized at any point with a variety of reactive groups, ligands or agents. The nucleic acid molecules of the invention may be generated by synthetic means or may be isolated from nature by protocols well known in the art (Sambrook, J., Fritsch, E. F. and Maniatis, T., Molecular Cloning: A Laboratory Manual, Cold Spring Harbor Laboratory Press, Cold Spring Harbor, N.Y., 1989).

It should be noted that functionalization of the nucleic acids are not necessary for their association with CNT's for the purpose of dispersion. Functionalization may be of interest after the CNT's have been dispersed and it is desired to bind other moieties to the nucleic acid or immobilize the carbon nanotube-nucleic acid complex to a surface through various functionalized elements of the nucleic acid. As used herein nucleic acids that are used for dispersion, typically lack functional groups and are referred to herein as “unfunctionalized”.

Peptide nucleic acids (PNA) are particularly useful in the present invention, as they possess the double functionality of both nucleic acids and peptides. Methods for the synthesis and use of PNA's are well known in the art, see for example Antsypovitch, S. I. Peptide nucleic acids: structure Russian Chemical Reviews (2002), 71(1), 71-83.

The nucleic acid molecules of the invention may have any composition of bases and may even consist of stretches of the same base (poly A or polyT for example) without impairing the ability of the nucleic acid molecule to disperse the bundled nanotube. Preferably the nucleic acid molecules will be less than about 2000 bases where less than 1000 bases is preferred and where from about 5 bases to about 1000 bases is most preferred. Generally the ability of nucleic acids to disperse carbon nanotubes appears to be independent of sequence or base composition, however there is some evidence to suggest that the less G-C and T-A base-pairing interactions in a sequence, the higher the dispersion efficiency, and that RNA and varieties thereof is particularly effective in dispersion and is thus preferred herein. Nucleic acid molecules suitable for use in the present invention include but are not limited to those having the general formula:
1. An wherein n=1−2000;
2. Tn wherein n=1−2000;
3. Cn wherein n=1−2000;
4. Gn wherein n=1−2000;
5. Rn wherein n=1−2000, and wherein R may be either A or G;
6. Yn wherein n=1−2000, and wherein Y may be either C or T;
7. Mn wherein n=1−2000, and wherein M may be either A or C;
8. Kn wherein n=1−2000, and wherein K may be either G or T;
9. Sn wherein n=1−2000, and wherein S may be either C or G;
10. Wn wherein n=1−2000, and wherein W may be either A or T;
11. Hn wherein n=1−2000, and wherein H may be either A or C or T;
12. Bn wherein n=1−2000, and wherein B may be either C or G or T;
13. Vn wherein n=1−2000, and wherein V may be either A or C or G;
14. Dn wherein n=1−2000, and wherein D may be either A or G or T; and
15. Nn wherein n=1−2000, and wherein N may be either A or C or T or G;

In addition the combinations listed above the person of skill in the art will recognize that any of these sequences may have one or more deoxyribonucleotides replaced by ribonucleotides (i.e., RNA or RNA/DNA hybrid) or one or more sugar-phosphate linkages replaced by peptide bonds (i.e. PNA or PNA/RNA/DNA hybrid). Once the nucleic acid molecule has been prepared it may be stabilized in a suitable solution. It is preferred if the nucleic acid molecules are in a relaxed secondary conformation and only loosely associated with each other to allow for the greatest contact by individual strands with the carbon nanotubes. Stabilized solutions of nucleic acids are common and well known in the art (see Sambrook supra) and typically include salts and buffers such as sodium and potassium salts, and TRIS (Tris(2-aminoethyl)amine), HEPES (N-(2-hydroxyethyl)piperazine-N′-(2-ethanesulfonic acid), and MES (2-(N-Morpholino)ethanesulfonic acid. Preferred solvents for stabilized nucleic acid solutions are those that are water miscible where water is most preferred.

Once the nucleic acid molecules are stabilized in a suitable solution they may be contacted with a population of bundled carbon nanotubes. It is preferred, although not necessary if the contacting is done in the presence of an agitation means of some sort. Typically the agitation means employs sonication for example, however may also include, devices that produce high shear mixing of the nucleic acids and nanotubes (i.e. homogenization), or any combination thereof. Upon agitation the carbon nanotubes will become dispersed and will form nanotube-nucleic acid complexes comprising at least one nucleic acid molecule loosely associated with the carbon nanotube by hydrogen bonding or some non-covalent means.

The process of agitation and dispersion may be improved with the optional addition of nucleic acid denaturing substances to the solution. Common denaturants include but are not limited to formamide, urea and guanidine. A non-limiting list of suitable denaturants may be found in Sambrook supra.

Additionally temperature during the contacting process will have an effect on the efficacy of the dispersion. Agitation at room temperature or higher was seen to give longer dispersion times whereas agitation at temperatures below room temperature (23° C.) were seen to give more rapid dispersion times where temperatures of about 4° C. are preferred.

Recovery of Dispersed Nanotubes

Once the nanotube-nucleic acid molecule complexes are formed they must be separated from solution as well as purified form any metallic particles which may interfere in the dispersion by the charged dispersant. Where the nucleic acid has been functionalized by the addition of a binding pair for example separation could be accomplished by means of immobilization thought the binding pair as discussed below. However, where the nucleic acid has not been functionalized an alternate means for separation must be found. Applicants have discovered that either gel electrophoresis chromatography or a phase separation method provide a rapid and facile method for the separation of nanotube-nucleic acid complexes into discreet fractions based on size or charge. These methods have been applied to the separation and recovery of coated nanoparticles (as described in U.S. Ser. No. 10/622,889 incorporated herein by reference) and have been found useful here.

Alternatively the complexes may be separated by two phase separation methods. In this method nanotube-nucleic acid complexes in solution are fractionated by adding a substantially water-miscible organic solvent in the presence of an electrolyte. The amount of the substantially water-miscible organic solvent added depends on the average particle size desired. The appropriate amount can be determined by routine experimentation. Typically, the substantially water-miscible organic solvent is added to give a concentration of about 5% to 10% by volume to precipitate out the largest particles. The complexes are collected by centrifugation or filtration. Centrifugation is typically done using a centrifuge, such as a Sorvall® RT7 PLUS centrifuge available from Kendro Laboratory Products (Newtown, Conn.), for about 1 min at about 4,000 rpm. For filtration, a porous membrane with a pore size small enough to collect the complex size of interest can be used. Optionally, sequential additions of the substantially water-miscible organic solvent are made to the complex solution to increase the solvent content of the solution and therefore, precipitate out complexes of smaller sizes.

After separation by anyone of the above methods it may be necessary to additionally filter the CNT's to remove any metallic particles which may interfere with the dispersion or alignment of the CNT's

Substrates

Solid substrates useful in the present invention are comprised of materials which include but are not limited to silicon, silicon dioxide, glass, metal, metal oxide, metal nitride, metal alloy, polymers, ceramics, and combinations thereof. Particularly suitable substrates will be comprised of for example, quartz glass, alumina, graphite, mica, mesoporous silica, silicon wafer, nanoporous alumina, silica, titania, ZnO₂, HfO₂, SnO₂, Ta₂O₃, TaN, SiN, Si₃N₄, and ceramic plates. Preferably, the substrate is quartz glass or silicon wafer.

Optionally it may be useful to prepare the surface of the solid substrate so that it will better receive and bind the nano-structures. For example the solid substrate, especially metal oxide surfaces, may be pre-treated, micro-etched or may be coated with materials for better nano-structure adhesion and alignment. Methods for coating SiO₂ and other oxide surfaces are well documented in the literature; see, for example, Chemically Modified Oxide Surfaces, Vol. 3 (edited by D. E. Leyden, W. T. Collins, Publisher: Taylor & Francis, Inc., 1990).

One method of pre-treatment involves reacting the metal oxide surface to form covalent bonds between a desired functional group and the surface. One pre-treatment is to make the surface more hydrophobic, such as but not limited to treating the surface with hydrocarbyl functional groups. A typical scheme for this type of chemical modification is to react a nucleophilic group with the hydroxyl groups on the oxide surface. A typical reaction is shown below, using SiO₂ to exemplify the metal oxide surface and R₃SiCl (where each R is one or more hydrocarbyl group) to exemplify the treatment reagent.

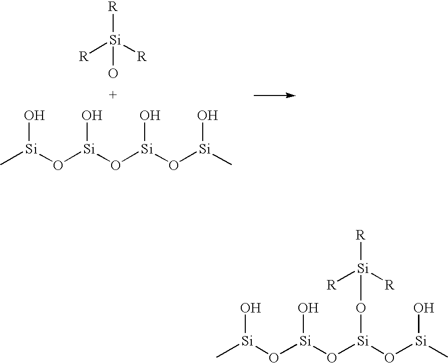

Any means known in the art can be used to affix the hydrocarbyl functional groups to the surface, preferably via covalent bonding between the functional groups and the surface.

By hydrocarbyl is meant a straight chain, branched or cyclic arrangement of carbon atoms connected by single, double, or triple carbon to carbon bonds and/or by ether linkages, and substituted accordingly with hydrogen atoms. Such hydrocarbyl groups may be aliphatic and/or aromatic. Examples of hydrocarbyl groups include methyl, ethyl, propyl, isopropyl, butyl, isobutyl, t-butyl, cyclopropyl, cyclobutyl, cyclopentyl, methylcyclopentyl, cyclohexyl, methylcyclohexyl, benzyl, phenyl, o-tolyl, m-tolyl, p-tolyl, xylyl, vinyl, allyl, butenyl, cyclohexenyl, cyclooctenyl, cyclooctadienyl, and butynyl. The hydrocarbyl group can be C1 to C30 in size.

Affixing CNT's to Substrates

In some situations it will be useful to immobilize or affix the CNT's to the surface of the substrate. This may be a first step in device fabrication or may be useful in CNT cutting methods.

Once a dispersed population of CNT's are prepared as described above they may be dissolved in an aqueous solution and deposited on the solid surface or substrate where they become spontaneously aligned. Generally the deposited CNT's will remain on the substrate for a period of time of about 15 sec to about 60 min for good deposition. At this point it may be useful to wash the substrate with a washing solution or solvent. The washing solvent is used to remove the solution after deposition of the nanotubes on the substrate. The solvent should be compatible and/or miscible with the solution containing the nanotubes. Preferably the solution is water or aqueous based, and should not leave any residue or impurities after removal.

After the surface is washed the CNT's will then be dried so as to affix them to the surface of the substrate. Drying can be accomplished by any means that does not damage the nanotubes. One preferred method is by passing a stream of gas over the substrate. Any gas may be used that is not reactive with the substrate or nanotubes.

After drying, the dispersant may be removed from the nanotubes by any chemical or physical means that will preferentially degrade the dispersant, such as but not limited to plasma, etching, enzymatic digestion, chemical oxidation, hydrolysis, and heating. One preferred method is by heating in the presence of oxygen.

After the tubes are aligned on the substrate, the nanotubes may be cut to a uniform length. Methods that can be used to cut the nanotubes include but are not limited to the utilization of ionized radiation including photon irradiation utilizing ionized radiation such as ultraviolet rays, X-rays, electron irradiation, ion-beam irradiation, plasma ionization, and neutral atoms machining, optionally through a photomask with a specific pattern. One such method is described in U.S. Patent Appl. 2004/003855, herein incorporated by reference. Optionally the CNT's may be cut according to other means well known in the art (see for example: Zhang et al., Structure of single-wall carbon nanotubes purified and cut using polymer, Appl. Phys. A 74, pp. 7-10, 2002; Yudasaka et al., Effect of an organic polymer in purification and cutting of single-wall carbon nanotubes, Appl. Phys. A 71, pp. 449-451, 2000; Rubio et al., A mechanism for cutting carbon nanotubes with a scanning tunneling microscope, Eur. Phys. J. B 17, pp. 301-308, 2000; Stepanek et al., Cutting single wall carbon nanotubes, Mat. Res. Soc. Sump. Proc. Vol. 593, 2000; and Park et al., Electrical cutting and nicking of carbon nanotubes using an atomic force microscope, Applied Physics Letters, Volume 80, No. 23, 10/06/2002).

In one embodiment it may be useful to begin with a population of CNT having a uniform length, and any of the above referenced methods for cutting CNT's may be used to process the CNT's prior to deposition to achieve that uniform length.

Optionally the methods of the present invention for aligning and affixing populations of carbon nanotubes on a substrate can be performed in the present of a weak external magnetic or electromagnetic field, preferably less than about 0.5 Tesla (5000 Gauss), more preferably less than about 0.25 Tesla, even more preferably 0.1 Tesla. By “external magnetic field” it is meant an artificially produced magnetic field other than the earth's natural magnetic field. It should be noted here that the use of an external magnetic field is not essential but may, in some cases, enhance the rate of alignment of the nanotubes on the substrate.

Alternatively it is possible to more precisely modulate the alignment of the CNT by the use of electrodes placed near or around the substrate. For example, the placement of a metallic mass at either end of a rectangular substrate will vary the amount and type of alignment. The metallic mass may be configured as an electrode, however it is not necessary for the mass to be conducing electrical current to produce the alignment effect. Typically, the CNT will align perpendicular to the metallic mass in regions of the substrate closest to the mass where the alignment will be more varied the further from the mass. The metallic mass may be comprised of a number of common metals such as Au, Ag, Ti, Pt, Pd, and Al.

The aligned nanotubes of the present invention are particularly useful in devices, especially nanodevices, such as but not limited to field effect transistors (FET), FET based sensors, biosensors, carbon nanotube-based thin-film transistors, carbon nanotube-based optical devices, carbon nanotube-based magnetic devices, field-emission display devices, lithographic-based cutting of carbon nanotubes, molecular transistors, and other optoelectronic devices, and single-electron devices

### EXAMPLES

The present invention is further defined in the following Examples. It should be understood that these Examples, while indicating preferred embodiments of the invention, are given by way of illustration only. From the above discussion and these Examples, one skilled in the art can ascertain the essential characteristics of this invention, and without departing from the spirit and scope thereof, can make various changes and modifications of the invention to adapt it to various uses and conditions.

General Methods:

Nucleic acids used in the following examples was obtained using standard recombinant DNA and molecular cloning techniques as described by Sambrook, supra, by T. J. Silhavy, M. L. Bennan, and L. W. Enquist, Experiments with Gene Fusions, Cold Spring Harbor Laboratory, Cold Spring Harbor, N.Y., 1984, and by Ausubel, F. M. et al., Current Protocols in Molecular Biology, Greene Publishing Assoc. and Wiley-Interscience, N.Y., 1987.

The meaning of abbreviations used is as follows: “min” means minute(s), “h” means hour(s), “μL” means microliter(s), “mL” means milliliter(s), “L” means liter(s), “nm” means nanometer(s), “mm” means millimeter(s), “cm” means centimeter(s), “μm” means micrometer(s), “mM” means millimolar, “M” means molar, “mmol” means millimole(s), “μmole” means micromole(s), “g” means gram(s), “μg” means microgram(s), “mg” means milligram(s), “g” means the gravitation constant, “rpm” means revolutions per minute,

### Example 1

### Purification of Carbon Nanotubes by Size-Exclusion Chromatography

This Example describes preparation of carbon nanotube materials used for experiments in the subsequent Examples. Unpurified single wall carbon nanotubes from Southwest Nanotechnologies (SWeNT, Norman, Okla.) and single-stranded DNA of either (GT)30 or random sequence were used as dispersion agents. Dispersion was done as described in U.S. 60/432,804 herein incorporated by reference. A size exclusion column Superdex 200 (16/60, prep grade) from Amersham Biosciences (Piscataway, N.J.)) was chosen for the HPLC purification. A volume of 2 mL of DNA-dispersed carbon nanotubes at a concentration of ˜100 μg/mL was injected into the column mounted on a BioCAD/SPRINT HPLC system (Applied Biosystems, Foster City, Calif.), and eluted by 120 mL of a pH 7 buffer solution containing 40 mM Tris/0.2M NaCl, at a flow rate of 1 mL/min. Fractions were collected in 1 mL aliquots. DNA-CNT hybrids eluted from the column after about 40 mL of elution volume. The earlier fractions contained longer and more pure DNA-CNT hybrids than later fractions, as shown by atomic force microscopy (AFM).

Purified DNA-CNTs were then exchanged into pure H₂O using Microcon® centrifugal filter YM-100 (Millipore, Bedford, Mass.) and diluted to a final concentration of about 2 μg/mL. This step served to remove any metallic particles or other impurities that could interfere with device fabrication or function.

### Example 2

### Deposition of DNA-CNT Solution on to Sio₂ Surface

Silicon chips (about 1 cm×2 cm) with different thickness (100 to 500 nm) of thermal oxide layer on substrates of different crystal orientation and doping were used for this experiment.

Typically the center of a 1 cm×2 cm chip, a 2.5 mm×2.5 mm square was marked to define the location for solution deposition of the CNT's. Immediately before deposition, the SiO₂ surface was scrubbed with Kimwipes® EX-L tissue (Kimberly-Clark, Roswell, Ga.) wetted with methanol. A 5 μL of DNA-CNT solution (2 μg/mL in water) was mixed with an equal volume of 20 mM Tris/0.5 mM EDTA pH7 buffer, and then the entire 10 mL mixture was deposited onto the area defined by a marked square. After a 15 min incubation at room temperature, the surface was rinsed with pure water and blown dried with N₂ gas.

### Example 3

### CNT Alignment Observation by Atomic Force Microscopy

After deposition the alignment of the CNT's was observed using atomic force microscopy (AFM)

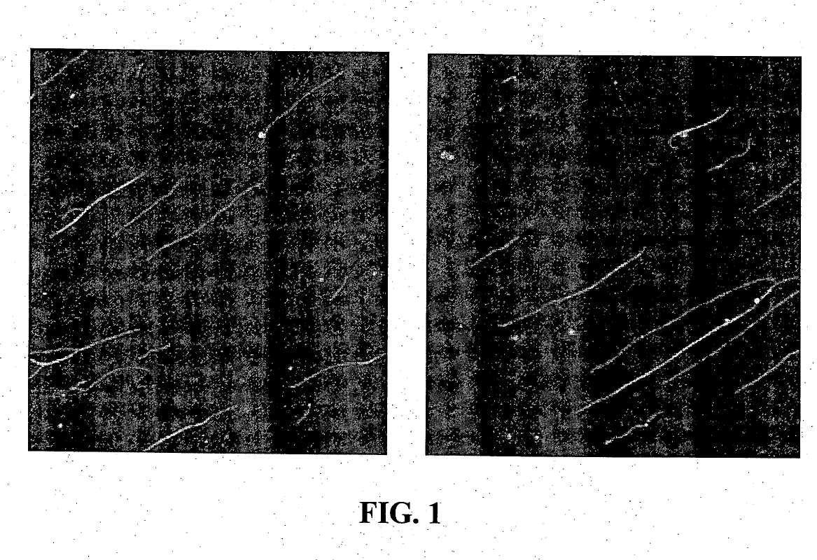

Tapping mode AFM was used to obtain height and phase imaging data simultaneously on a Nanoscope IIIa AFM, Dimension 3000 from Digital Instruments, (Santa Barbara, Calif.). Microfabricated cantilevers or silicon probes (Nanoprobes®, Digital Instruments) with 125 micron long cantilevers were used at their fundamental resonance frequencies which typically varied from 270-350 kHz depending on the cantilever. The cantilevers had a very small tip radius of 5-10 nm. The AFM was operated in ambient conditions with a double vibration isolation system. Extender electronics were used to obtain height and phase information simultaneously. AFM data were obtained in tapping mode, in air, using previously described methods. FIG. 1 shows the alignment orientation at two different spots on the chip for CNT's deposited as described in example 2. As can been seen in the figure the CNT's are well aligned in both places on the substrate.

### Example 4

### Alignment Independence of DNA Sequence and CNT Length

This Example demonstrates that the alignment of CNT's observed in Example 3 was independent of DNA sequence and CNT length.

A 60 bp long random ssDNA sequence was used to disperse and purify CNT following the procedure described in Example 1. The DNA-CNT solution was then deposited on a SiO₂/Si surface following the procedure described in Example 2. AFM measurement revealed similar CNT alignment as shown in Example 3. Similarly, CNT's of different lengths obtained by the size-exclusion fractionation described in Example 1 were tested for alignment. In all cases, CNT alignment was observed by AFM (data not shown). The alignment was shown to be independent of DNA sequence or CNT length.

### Example 5

### DNA-CNT Alignment on Non Silicon Substrates

This Example illustrates that CNT alignment can also be observed on surfaces other than SiO₂/Si surface.

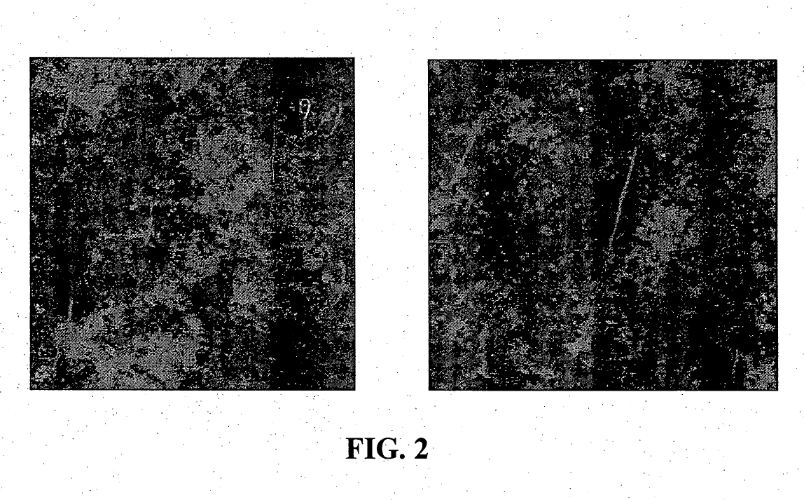

CNT's were prepared as described in Examples 1 and 2 and deposited on Corning barium borosilicate 7059 glass in the place of SiO2. Alignment was observed using AFM as described in Example 3. FIG. 2 shows DNA-CNT alignment on Corning 7059 glass. Referring to FIG. 2, two images (3 μm×3 μm) are taken from two different spots on the glass substrate As can be seen, in each image the nanotubes are aligned along a particular direction, indicating alignment on a non-silicon substrate according to the method of the invention.

### Example 6

### Dependence of CNT Alignment on Magnetic Field

This example illustrates that the alignment phenomenon seen by the solution deposition of CNT's on a surface is independent of external magnetic fields.

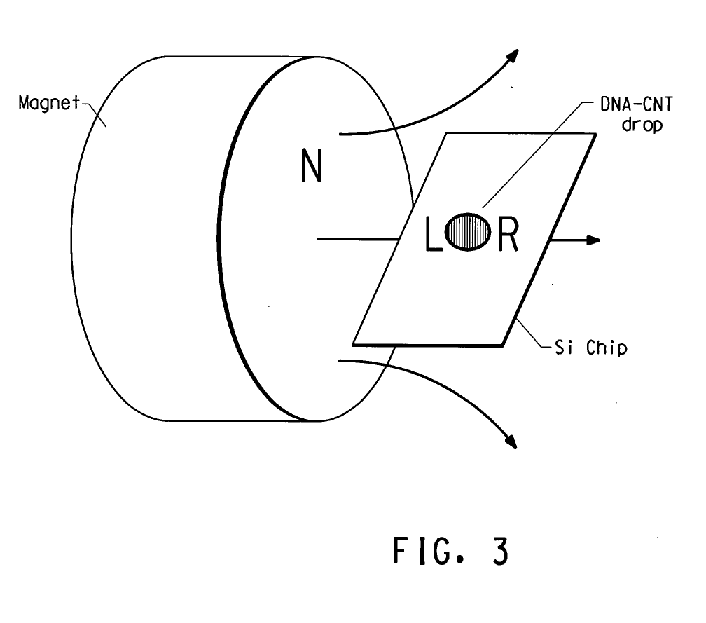

To test magnetic field effect, the deposition protocol described in Example 2 was carried out in a magnetic field under a configuration as shown in FIG. 3.

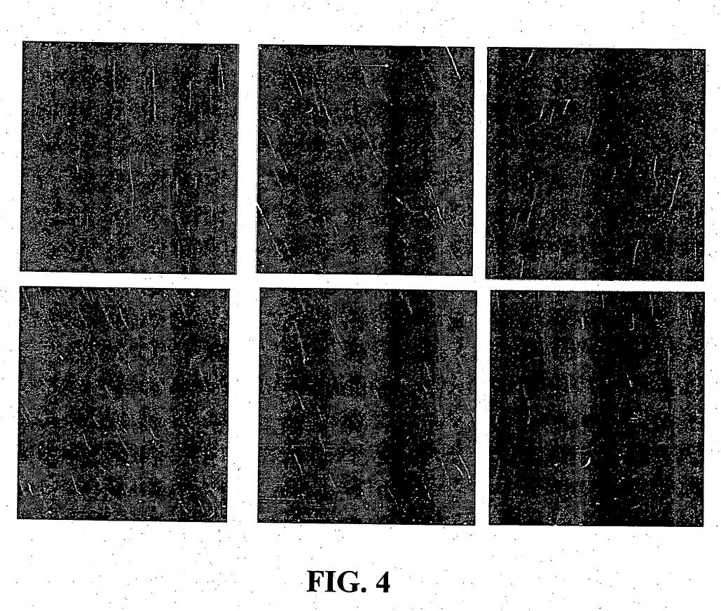

The experiment was carried out in the presence of a magnetic separation rack (New England BioLabs (Beverly, Mass.)). The magnet was a Neodymium rare earth permanent magnet, which generated a gradient field as illustrated by the arrows in FIG. 3. The field strength at the left (L) and right (R) edge of the drop was about 2500 Gauss and about 1500 Gauss (0.25 to 0.15 Tesla), respectively, as measured by a Gauss meter. Alignment of DNA-CNT was observed either with or without magnetic field and the results are shown in FIG. 4. Referring to FIG. 4, a total of six 6 μm×6 μm images are shown, taken within an area of 1400 μm×1400 μm on the substrate. As can be seen, within each image, nanotubes are well aligned along one particular direction. Moving form left to right beginning with the top left image, a slight variation of the alignment orientation is observed. The overall variation is estimated to be ≦20°, suggesting that magnetic field exerts an alignment force onto the DNA-CNT. This interaction is further supported by Example 7.

### Example 7

### Magnetic Force Microscopy of DNA-CNT

In addition to normal Tapping Mode AFM, when using a magnetic AFM tip one can map magnetic forces associated with the DNA-CNT that are dispersed on the substrate. Magnetic Force Microscopy (MFM) is a secondary imaging mode derived from Tapping Mode. This is performed through a two-pass technique, where the probe is lifted off the surface to be scanned (Lift Mode). Lift Mode separately measures topography and magnetic force using the topographical information to track the probe tip at a constant height (Lift Height) above the sample surface during the second pass. The MFM probe tip is coated with a ferromagnetic thin film. While scanning, it is the magnetic field's dependence on tip-sample separation that induces changes in the cantilever's resonance frequency or phase. MFM can be used to image both naturally occurring and deliberately written domain structures in magnetic materials.

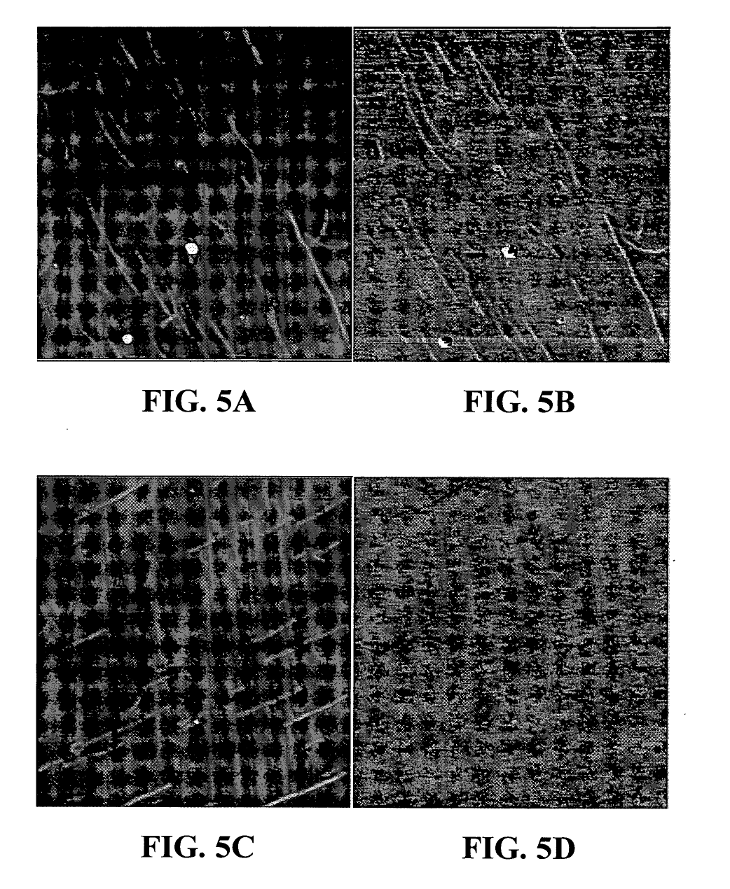

In this example MFM was used to image magnetic forces for DNA-CNT dispersed on SiO₂. FIG. 5 shows deposited DNA-CNT as prepared in Example 2 under the influence of a well-defined magnetic signal. FIGS. 5a and 5b show the AFM and MFM images, respectively, of the DNA-CNT sample, where the CNT's are associated with the polymer dispersant. As the MFM image reproduces the topography profile given by the AFM image, this result indicates that DNA-CNT hybrids possess magnetic moment.

In order to determine if the origin of the magnetic moment the deposited CNT's we due to the presence of the polymer dispersant, the substrates were heated to 350° C. for 2 hours to remove any DNA form the CNT. FIGS. 5c and 5d show the AFM and MFM images, respectively after DNA removal. It was clear that after DNA removal the magnetic signal was greatly reduced, suggesting that the magnetic forces are not primarily attributable to the CNT's themselves. This result indicates that DNA-CNT complex does possess a magnetic moment.

### Example 8

### Controlled Hydrophobic Layer Formation for Global Alignment

This Example describes a method for making a hydrophobic layer on the SiO₂ surface and the resulted improvement in DNA-CNT alignment. A commercially available silylation agent Sigmacote® (Sigma-Aldrich) was used. In a typical experiment, 50 μL of Sigmacote® was deposited onto the clean SiO₂ surface of a 1 cm×2 cm chip. The volume of the agent should be enough to cover the entire surface. After 30 sec. incubation, the treated chip was rinsed with pure water. Since the treated surface became hydrophobic, rinsing did not leave any water on the surface. Carbon nanotube deposition was then done the same way as described in Example 2. A 5 μL of DNA-CNT solution (2 μg/mL in water) was mixed with an equal volume of 20 mM Tris/0.5 mM EDTA pH7 buffer, and then the entire 10 mL mixture was deposited onto the treated surface. After a 15 min incubation at room temperature, the surface was rinsed with pure water and blown dried with N₂ gas.

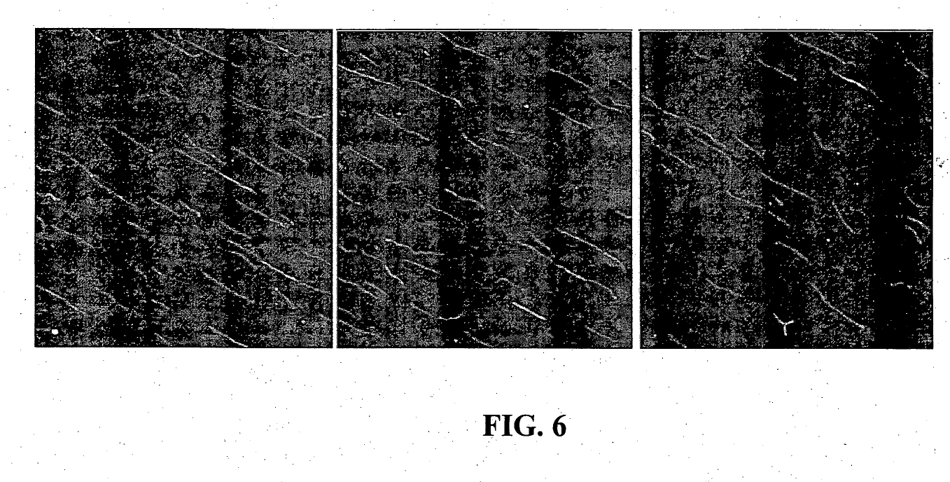

It was found that the alignment of DNA-CNT on the treated surface became very consistent across the entire deposition area. FIG. 6 shows three 3 μm×3 μm AFM images taken at three different spots ˜500 μm apart from each other. These demonstrate consistent alignment direction at the three spots.

### Example 9

### Metal Electrode Control of CNT Alignment

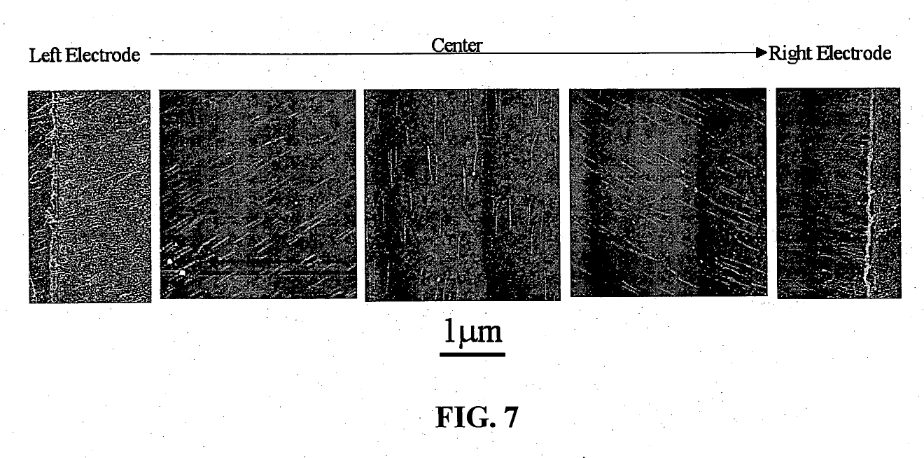

This Example demonstrates that one can use metal electrode patterns to control DNA-CNT alignment. A pair of Au electrodes 0.8 mm square, separated by 0.5 mm were deposited on a Si substrate by conventional photolithography. The substrate was then coated with Sigmacote® as described in Example 8. DNA-CNTs were deposited in the region between the two electrodes following procedures described in Example 2. AFM measurements showed the following characteristics as shown in FIG. 7:

a) near the two electrodes, DNA-CNTs are aligned nearly perpendicular to the electrode boundary line;

b) as one moves towards the center, DNA-CNTs gradually become parallel to the electrode boundary line.

What is claimed is:

1. A method for aligning a population of carbon nanotubes on a substrate comprising:
a) providing a population of carbon nanotubes associated with a charged dispersant in solution;
b) depositing the solution of (a) on a substrate whereby the population of carbon nanotubes are aligned.

2. A method for affixing a population of aligned carbon nanotubes on a substrate comprising:
a) providing a population of carbon nanotubes associated with a charged dispersant in solution;
b) depositing the solution of (a) on a substrate whereby the population of carbon nanotubes are aligned;
c) washing the substrate of (b) with a washing solvent; and
d) drying the washed substrate of (c) whereby the aligned carbon nanotubes are affixed to the substrate.

3. A method according to claim 2 wherein the solution of (b) remains on the substrate for a period of time ranging from about 15 s to about 60 min.

4. A method according to claim 2 wherein the drying of step (d) is accomplished by a stream of gas.

5. A method according to claim 2 wherein the washing solvent is aqueous based.

6. A method according to either claim 1 or claim 2 wherein the charged dispersant is a polymer.

7. A method according to claim 6, wherein the polymer is a biopolymer.

8. A method according to claim 7 wherein the biopolymer is selected from the group consisting of nucleic acids, polypeptides, and peptide nucleic acids.

9. A method according to either of claims 1 or 2 wherein the substrate is selected from the group consisting of silicon, silicon dioxide, glass, metal, metal oxide, metal nitride, metal alloy, polymers, ceramics, and combinations thereof.

10. A method according to claim 9 wherein the substrate is coated with a hydrophobic layer.

11. A method according to claim 10 wherein the hydrophobic layer is comprises hydrocarbyl groups.

12. A method according to claim 11 wherein the hydrocarbyl groups are selected from the group consisting of methyl, ethyl, propyl, isopropyl, butyl, isobutyl, t-butyl, cyclopropyl, cyclobutyl, cyclopentyl, methylcyclopentyl, cyclohexyl, methylcyclohexyl, benzyl, phenyl, o-tolyl, m-tolyl, p-tolyl, xylyl, vinyl, allyl, butenyl, cyclohexenyl, cyclooctenyl, cyclooctadienyl, and butynyl.

13. A method according to either of claims 1 or 2 wherein the solution is at a pH of about 3 to about 11.

14. A method according to claim 1 wherein the solution is aqueous based.

15. A method according to claim 2 wherein the dispersant is optionally removed from the carbon nanotube after the drying step of (d).

16. A method according to either of claims 1 or 2 wherein the population of carbon nanotubes is substantially free of metallic particles.

17. A method according to either of claims 1 or 2 wherein the population of carbon nanotubes are of uniform length.

18. A method according to either of claims 1 or 2 wherein the carbon nanotubes are single walled.

19. A method according to either of claims 1 or 2 wherein the carbon nanotubes are multi-walled.

20. A method according to either of claims 1 or 2 wherein the carbon nanotubes are semiconducting.

21. A method according to either of claims 1 or 2 wherein the carbon nanotubes are metallic.

22. A method according to either of claims 1 or 2 wherein the carbon nanotubes are singly dispersed.

23. A method according to either of claims 1 or 2 wherein the alignment is performed in the presence of an external magnetic or electromagnetic field.

24. A substrate comprising a population of singly dispersed aligned carbon nanotubes.

25. A substrate according to claim 21 wherein the carbon nanotubes are associated with a charged dispersant.

26. A substrate comprising a population of aligned carbon nanotubes made by the process of either of claims 1 or 2.

27. A device comprising the substrate of claim 24 or 25.

28. A device according to claim 27 wherein the device is selected from the group consisting of a FET, FET based sensors, biosensors, carbon nanotube-based thin-film transistors, carbon nanotube -based optical devices, carbon nanotube-based magnetic devices, and lithographic-based carbon nanotube devices.

29. A method of obtaining a population of carbon nanotubes of uniform length comprising:
a) providing a population of carbon nanotubes associated with a charged dispersant in solution;
b) depositing the solution of (a) on a substrate whereby the population of CNT is aligned;
c) washing the substrate of (b) with a washing solvent;
d) drying the washed substrate of (c) whereby the aligned carbon nanotubes are affixed to the substrate; and
e) cutting the aligned carbon nanotubes affixed to the substrate to a defined length.

30. A method according to claim 1 wherein the substrate is bounded on each edge by a metallic mass.

31. A method according to claim 30 wherein the metallic mass is comprised of materials selected from the group consisting of include Au, Ag, Ti, Pt, Pd, and Al.
